(19) United States
(12) Patent Application Publication
(10) Pub. No.: US 2025/0233096 A1
(43) Pub. Date: Jul. 17, 2025

(54) WIRING STRUCTURE, SEMICONDUCTOR PACKAGE INCLUDING THE WIRING STRUCTURE AND METHOD OF MANUFACTURING THE WIRING STRUCTURE

(71) Applicant: SAMSUNG ELECTRONICS CO., LTD., SUWON-SI (KR)

(72) Inventors: SOYEON MOON, Suwon-si (KR); SEUNG HUN CHAE, Suwon-si (KR); UN-BYOUNG KANG, Suwon-si (KR)

(21) Appl. No.: 18/775,463

(22) Filed: Jul. 17, 2024

(30) Foreign Application Priority Data
Jan. 15, 2024 (KR) 10-2024-0006322

(51) Int. Cl. H01L 23/00; H01L 23/31

(52) U.S. Cl. CPC H01L 24/20; H01L 23/3107; H01L 24/19; H01L 2224/19; H01L 2224/2101

(57) ABSTRACT

A wiring structure includes: a plurality of wiring layers and a plurality of insulating layers. The plurality of wiring layers include a first wiring layer that include a wiring pattern and a cavity, and the plurality of insulating layers include a first insulating layer that fills the cavity, and a second insulating layer that contacts each of the first wiring layer and the first insulating layer and covers the first wiring layer and the first insulating layer.

### CROSS-REFERENCE TO RELATED APPLICATION

This application claims priority under 35 U.S.C. 119 from Korean Patent Application No. 10-2024-0006322, filed in the Korean Intellectual Property Office on Jan. 15, 2024, the contents of which are herein incorporated by reference in their entirety.

### TECHNICAL FIELD

Embodiments of the present disclosure are directed to a wiring structure, a semiconductor package that includes the wiring structure, and a method of manufacturing the wiring structure.

### DISCUSSION OF THE RELATED ART

There are cases in which a wiring pattern with a cavity is formed in a wiring structure of a semiconductor package for the purpose of evaluating impedance characteristics and the like. For example, when a void occurs in an insulating layer that fills the cavity, the void expands at a curing temperature of the insulating layer, so that an upper wiring layer may be abnormally formed. For example, when the insulating layer is opened to expose the void, a plating material used to form the upper wiring layer may flow into the cavity, causing an electrical short circuit between the wiring layers.

### SUMMARY

An embodiment of the present disclosure provides a wiring structure that prevents defects due to voids formed in an insulating layer, and a semiconductor package that includes the wiring structure and a method of manufacturing the wiring structure.

An embodiment of the present disclosure provides a wiring structure that includes a plurality of wiring layers and a plurality of insulating layers. The plurality of wiring layers include a first wiring layer that includes a wiring pattern that includes a cavity, and the plurality of insulating layers include a first insulating layer that fills the cavity, and a second insulating layer that contacts each of the first wiring layer and the first insulating layer and covers the first wiring layer and the first insulating layer.

Another embodiment of the present disclosure provides a semiconductor package that includes a wiring structure that includes a plurality of wiring layers and a plurality of insulating layers, a support substrate disposed on the wiring structure and that includes a through hole, a semiconductor chip disposed in the through hole and electrically connected to the wiring structure; and an encapsulant that fills the through hole and encapsulates the semiconductor chip. The plurality of wiring layers include a first wiring layer that includes a wiring pattern and a cavity, and the plurality of insulating layers include a first insulating layer that fills the cavity, and a second insulating layer that contacts each of the first wiring layer and the first insulating layer and covers the first wiring layer and the first insulating layer.

Another embodiment of the present disclosure provides a method of manufacturing a wiring structure that includes: forming a wiring layer that includes a wiring pattern and a cavity, forming a first insulating layer that fills the cavity, and forming a second insulating layer that covers the wiring layer and the first insulating layer by contacting each of the wiring layer and the first insulating layer.

According to embodiments of the present disclosure, a wiring structure, a semiconductor package that includes the wiring structure, and a method of manufacturing the wiring structure that prevent defects due to voids formed in an insulating layer are provided.

### BRIEF DESCRIPTION OF THE DRAWINGS

FIG. 1 is a cross-sectional view of a semiconductor package according to a comparative example.

FIG. 2 is a plan view of area “A” of FIG. 1.

FIG. 3 is a cross-sectional view of a semiconductor package according to an embodiment.

FIG. 4 is an enlarged view of area “A” of FIG. 3.

FIG. 5 is a cross-sectional view of a semiconductor package according to an embodiment.

FIG. 6 is a cross-sectional view of a semiconductor package according to an embodiment.

FIG. 7 is an enlarged view of area “A” of FIG. 6.

FIG. 8 is a cross-sectional view of a semiconductor package according to an embodiment.

FIG. 9 to FIG. 13 illustrate defects caused by voids formed in an insulating layer during a manufacturing process of a wiring structure of a semiconductor package.

FIG. 14 to FIG. 18 illustrate a process of manufacturing a wiring structure of a semiconductor package according to an embodiment.

FIG. 19 to FIG. 22 illustrate a process of manufacturing a wiring structure of a semiconductor package according to an embodiment.

### DETAILED DESCRIPTION

Hereinafter, embodiments of the present disclosure will be described more fully hereinafter with reference to the accompanying drawings, in which various embodiments of the disclosure are shown. As those skilled in the art would realize, described embodiments may be modified in various different ways, all without departing from the spirit or scope of the present disclosure.

Identical or similar constituent elements throughout the specification may be denoted by the same reference numerals.

Throughout this specification and the claims that follow, when it is described that an element is “coupled or connected” to another element, the element may be “directly coupled or connected” to the other element or “indirectly coupled or connected” to the other element through a third element. In a similar point of view, this includes not only “physically connected” but also “electrically connected.”

It will be understood that when an element such as a layer, film, region, area, or substrate is referred to as being “on” or “above” another element, it can be directly on the other element or intervening elements may also be present.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, situations that may occur in a semiconductor package will be described through a comparative example with reference to the accompanying drawings, and embodiments for improving them will be described.

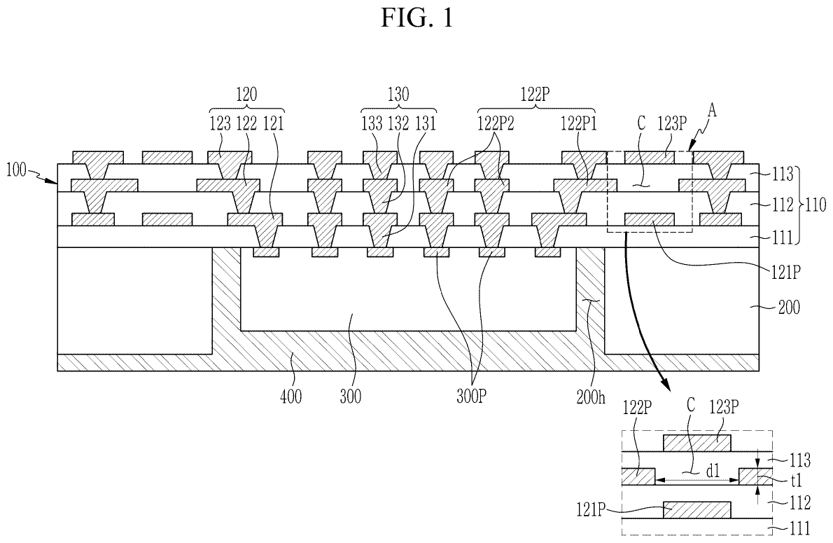

FIG. 1 is a cross-sectional view of a semiconductor package according to a comparative example.

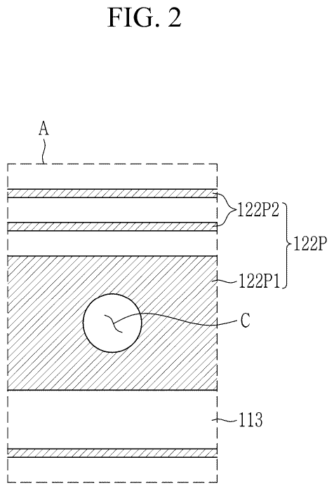

FIG. 2 is a plan view of area “A” of FIG. 1.

Referring to the drawings, in an embodiment, a semiconductor package includes a wiring structure 100, a support substrate 200 disposed on the wiring structure 100 and that includes a through hole 200h, a semiconductor chip 300 disposed in the through hole 200h and electrically connected to the wiring structure 100, and an encapsulant 400 that fills the through hole 200h and encapsulates the semiconductor chip 300.

The wiring structure 100 includes a plurality of insulating layers 110, a plurality of wiring layers 120, and a plurality of vias 130. For example, the wiring structure 100 include a first insulating layer 111, a first wiring layer 121 disposed on the first insulating layer 111, first vias 131 that penetrate the first insulating layer 111 and electrically connect the first wiring layer 121 to the semiconductor chip 300, a second insulating layer 112 disposed on the first insulating layer 111 and that covers the first wiring layer 121, a second wiring layer 122 disposed on the second insulating layer 112, second vias 132 that penetrate the second insulating layer 112 and electrically connect the second wiring layer 122 to the first wiring layer 121, a third insulating layer 113 disposed on the second insulating layer 112 and that covers the second wiring layer 122, a third wiring layer 123 disposed on the third insulating layer 113, and third vias 133 that penetrate the third insulating layer 113 and electrically connect the third wiring layer 123 to the second wiring layer 122. However, the number of each of the insulating layers 110, the wiring layers 120, and the vias 130 included in the wiring structure 100 is not necessarily limited to the number shown in the drawings.

An insulating material is used for each of the plurality of insulating layers 110, and, for example, a photosensitive insulating material such as a photo-imagable dielectric (PID) that can realize a fine pitch through a photoresist process can be used.

Each of the plurality of wiring layers 120 includes wiring patterns. Each wiring pattern in the wiring layer 120 is one of a signal pattern, a power pattern, a ground pattern, etc.

For example, the first wiring layer 121 includes a first wiring pattern 121P, the second wiring layer 122 includes a second wiring pattern 122P1 that includes a cavity C, and the third wiring layer 123 includes a third wiring pattern 123P. The second wiring pattern 122P1 that includes the cavity C is used to evaluate impedance characteristics of a wiring structure. The first wiring pattern 121P is disposed on a first side of the cavity C, and the third wiring pattern 123P is disposed on a second side of the cavity C. Each of the first wiring pattern 121P and the third wiring pattern 123P may be a ground pattern for evaluating impedance characteristics.

The cavity C of the second wiring pattern 122P1 has a large diameter, and thus, voids can easily occur when the cavity C is filled with an insulating material. For example, a diameter d1 of the cavity C of the second wiring pattern 122P1 is about 300 μm. However, a thickness t1 of the second wiring layer 122 that includes the second wiring pattern 122P1 is as thin as about 5 μm.

In addition, the second wiring layer 122 includes additional wiring patterns 122P2 other than the second wiring pattern 122P1, and in some embodiments, the insulating material that fills the cavity C differs from the insulating material that fills the space between the second wiring pattern 122P1 and the additional wiring pattern 122P2 and the space between the additional wiring patterns 122P2, which will be described below.

The via 130 has a tapered shape whose diameter decreases in a direction from one surface toward the other surface. For example, the via 130 has a tapered shape whose diameter decreases in a direction from the third insulating layer 113 toward the first insulating layer 111. However, the via 130 may have other shapes such as a cylindrical shape.

A conductive material is used for each of the plurality of wiring layers 120 and the via 130, such as at least one of aluminum (Al), copper (Cu), gold (Au), silver (Ag), platinum (Pt), tin (Sn), chromium (Cr), palladium (Pd), lead (Pb), titanium (Ti), or an alloy thereof. In addition, the via 130 is integrally formed with the wiring layer 120 so that there is no boundary therebetween. For example, the first via 131 is integrally formed with the first wiring layer 121, the second via 132 is integrally formed with the second wiring layer 122, and the third via 133 is integrally formed with the third wiring layer 123.

The support substrate 200 is an insulating substrate that provides rigidity to the semiconductor package. However, the support substrate 200 is not an essential component of the semiconductor package, and the semiconductor package might not include the support substrate 200. When the semiconductor package does not include the support substrate 200, the encapsulant 400 that encapsulates the semiconductor chip 300 is exposed by the side surface of the semiconductor package.

The semiconductor chip 300 includes a connection pad 300P disposed on one surface, and the surface on which the connection pad 300P is disposed faces the wiring structure 100. The type of the semiconductor chip 300 is not particularly limited, and may be a logic chip, a memory chip, etc.

The encapsulant 400 protects the semiconductor chip 300 from physical, mechanical, and/or chemical damage. The material of the encapsulant 400 may be an epoxy molding compound (EMC), but is not necessarily limited thereto. The encapsulant 400 fills the through hole 200h of the support substrate 200, and extends on the surface opposite to the surface that faces the wiring structure 100 of the support substrate 200 and covers the support substrate 200.

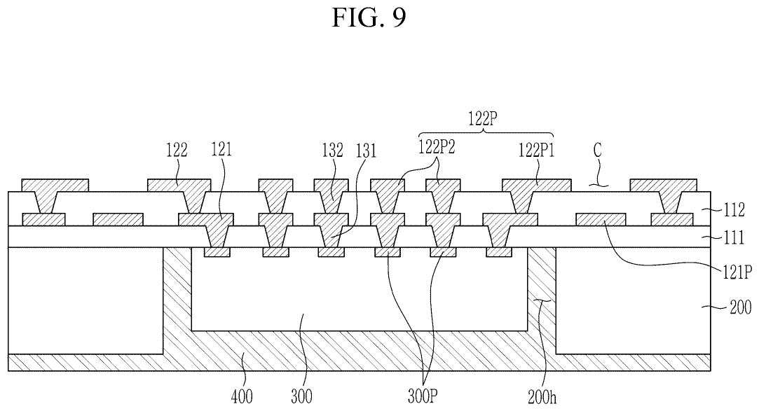

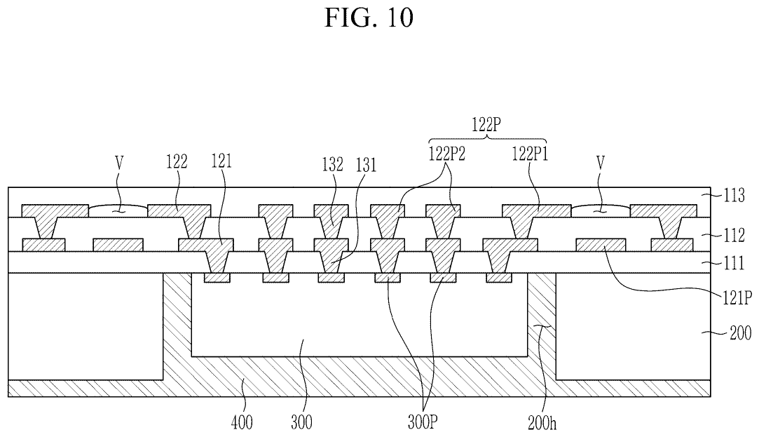

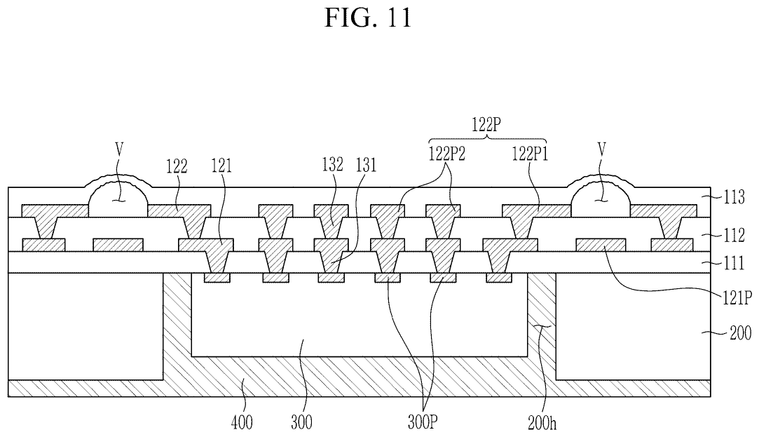

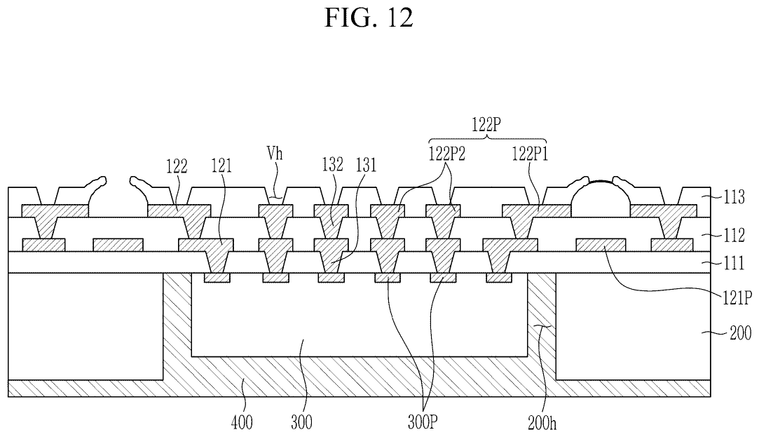

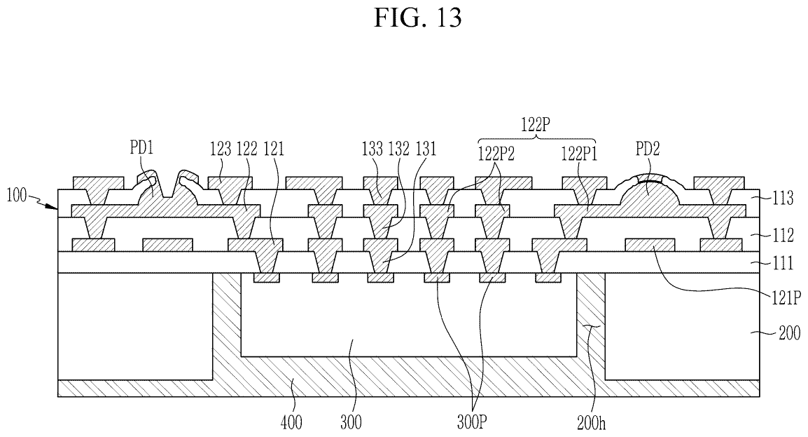

Referring to FIG. 9 to FIG. 13, in some embodiments, in a manufacturing process of a semiconductor package of FIG. 1, a defect can occur in the semiconductor package when a void V occurs in the third insulating layer 113 that fills the cavity C. For example, when the insulating material that forms the third insulating layer 113 is coated on the second insulating layer 112 and the second wiring layer 122, the cavity C of the second wiring pattern 122P1 might not be filled with the insulating material, so the void V occurs (see FIG. 10). The void V may further expand at a curing temperature, such as about 117° C., of the insulating material (see FIG. 11). In addition, in a developing process that forms a via hole Vh, the third insulating layer 113 that covers the void can open to expose the void V (see FIG. 12). For example, in a plating process that forms the third wiring layer 123, a plating material flows into the cavity C through the exposed void V, causing plating defects PD1 and PD2 that cause electrical short circuits between the wiring layers.

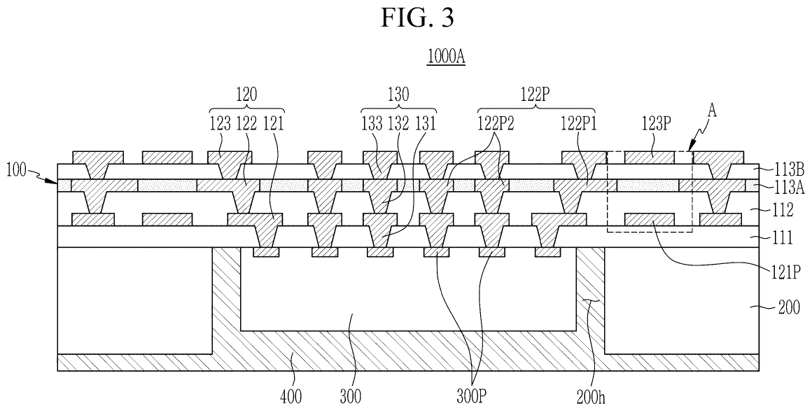

FIG. 3 is a cross-sectional view of a semiconductor package according to an embodiment.

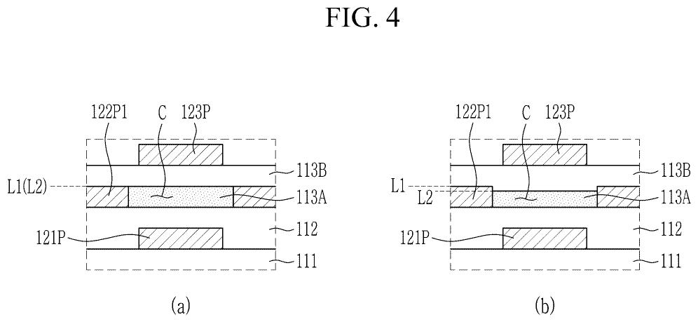

FIG. 4 is an enlarged view of area “A” of FIG. 3.

A wiring structure 100 of a semiconductor package 1000A includes a plurality of insulating layers 113A and 113B disposed between a second insulating layer 112 and a third wiring layer 123. For example, the wiring structure 100 includes a first insulating layer 111, a first wiring layer 121 disposed on the first insulating layer 111, first vias 131 that penetrating the first insulating layer 111 and electrically connect the first wiring layer 121 to the semiconductor chip 300, a second insulating layer 112 disposed on the first insulating layer 111 and that covers the first wiring layer 121, a second wiring layer 122 disposed on the second insulating layer 112, second vias 132 that penetrate the second insulating layer 112 and electrically connect the second wiring layer 122 to the first wiring layer 121, a third insulating layer 113A disposed on the second insulating layer 112, a fourth insulating layer 113B disposed on the second wiring layer 122 and the third insulating layer 113A, a third wiring layer 123 disposed on the fourth insulating layer 113B, and third vias 133 that penetrate the fourth insulating layer 113B and electrically connect the third wiring layer 123 and the second wiring layer 122.

The third insulating layer 113A is disposed on the second insulating layer 112 together with the second wiring layer 122 and fills at least a portion of the cavity C of the second wiring pattern 122P1. In an embodiment, the third insulating layer 113A is disposed between the second insulating layer 112 and the fourth insulating layer 113B. Accordingly, the third insulating layer 113A covers side surfaces of the wiring patterns 122P1 and 122P2 in the second wiring layer 122 and is exposed by side surfaces of the wiring structure 100. In addition, the third insulating layer 113A fills a space between the second wiring pattern 122P1 and the additional wiring pattern 122P2, and a space between the additional wiring patterns 122P2.

An insulating material is used for the third insulating layer 113A, and a different material is sued for the fourth insulating layer 113B. For example, the third insulating layer 113A is formed of an Ajinomoto build-up film (ABF), and the fourth insulating layer 113B is formed of a PID. However, embodiments of the present disclosure are not necessarily limited thereto, and in some embodiments, the third insulating layer 113A and the fourth insulating layer 113B include the same material.

A molecular weight of the third insulating layer 113A is 30,000 or more. When the molecular weight of the third insulating layer 113A is 30,000 or more, the third insulating layer 113A is easily formed by laminating the insulating material.

A coefficient of thermal expansion (CTE) of the third insulating layer 113A is 100 ppm/° C. or less to minimize warpage. In addition, the third insulating layer 113A should have a dielectric constant (k) of 4 or less to ensure excellent insulating properties.

When a plurality of insulating layers 111, 112, 113A, and 113B include a thermosetting material, the curing temperature of the third insulating layer 113A is the same as or less than the curing temperature of the other insulating layers 111, 112, and 113B. When the curing temperature of the third insulating layer 113A is higher than the curing temperature of the other insulating layers 111, 112, and 113B, due to the additional process condition for curing the third insulating layer 113A, the process may be more complicated and a incur a cost burden due to additional equipment.

The fourth insulating layer 113B is directly disposed on the second wiring layer 122 and the third insulating layer 113A. Accordingly, the fourth insulating layer 113B is in contact with each of the second wiring layer 122 and the third insulating layer 113A and covers the second wiring layer 122 and the third insulating layer 113A.

Referring to FIG. 4 (a) and (b), in an embodiment, a level L2 of one surface of the third insulating layer 113A covered with the fourth insulating layer 113B may be the same as a level L1 of one surface of the second wiring pattern 122P1 covered with the fourth insulating layer 113B, or may be lower than a level L1 of the one surface of the second wiring pattern 122P1. As will be described below, the third insulating layer 113A is formed by laminating an insulating material, and by removing the insulating material formed on the second wiring layer 122 after laminating, the level of the third insulating layer 113A may be at the same as or lower than a level of the one surface of the second wiring pattern 122P1.

A surface of each of the second wiring pattern 122P1 and the third insulating layer 113A that are opposite to a surface covered with the fourth insulating layer 113B, such as surfaces that contact the second insulating layer 112, are coplanar.

According to an embodiment of the present disclosure, the third insulating layer 113A is formed that fills the cavity C of the second wiring pattern 122P1 with an insulating material, and then the fourth insulating layer 113B is formed that covers the second wiring layer 122 and the third insulating layer 113A, so that since no void is formed in the cavity C, defects that can occur in the wiring structure 100 are prevented.

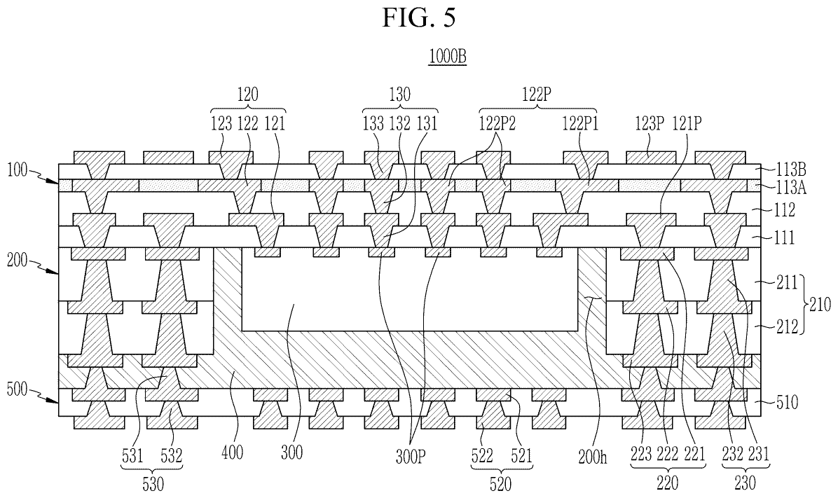

FIG. 5 is a cross-sectional view of a semiconductor package according to an embodiment.

Referring to FIG. 5, in an embodiment, a support substrate 200 of a semiconductor package 1000B includes one or more insulating layers 210 and one or more wiring layers 220 electrically connected to the wiring structure 100. In addition, the semiconductor package 1000B further includes a wiring structure 500 disposed on the support substrate 200 and the encapsulant 400.

For example, the support substrate 200 of the semiconductor package 1000B includes a first wiring layer 221, a first insulating layer 211 that covers the first wiring layer 221, a second wiring layer 222 disposed on the first insulating layer 211; a second insulating layer 212 disposed on the first insulating layer 211 and that covers the second wiring layer 222, and a third wiring layer 223 disposed on the second insulating layer 212.

The first wiring layer 221 is disposed at the lowermost side of the plurality of wiring layers 220 and is electrically connected to the first wiring layer 121 through the first via 131 of the wiring structure 100.

In addition, the support substrate 200 further includes vias 230 that electrically connect the wiring layers 220 disposed on different layers. For example, the support substrate 200 includes first vias 231 that electrically connect the first wiring layer 221 to the second wiring layer 222, and second vias 232 that electrically connect the second wiring layer 222 to the third wiring layer 223.

An insulating material is used for each of the plurality of insulating layers 210, such as at least one of prepreg, Ajinomoto build-up film (ABF), etc.

Each of the plurality of wiring layers 220 also includes wiring patterns, such as a signal pattern, a power pattern, and/or a ground pattern.

The via 230 have a tapered shape whose diameter decreases in a direction from one surface toward the other surface. For example, the via 230 have a tapered shape whose diameter decreases in a direction from the second insulating layer 212 toward the first insulating layer 211. However, embodiments are not necessarily limited thereto, and in some embodiments, the via 230 have other shapes such as a cylindrical shape.

In addition, a conductive material is used for each of the plurality of wiring layers 220 and the via 230, such as at least one of aluminum (Al), copper (Cu), gold (Au), silver (Ag), platinum (Pt), tin (Sn), chromium (Cr), palladium (Pd), lead (Pb), titanium (Ti), or an alloy thereof. In addition, the via 230 is integrally formed with the wiring layer 220 so that there is no boundary therebetween. For example, the first via 231 is integrally formed with the second wiring layer 222, and the second via 232 is integrally formed with the third wiring layer 223.

The wiring structure 500 electrically connects the semiconductor package 1000B to another semiconductor package or a semiconductor chip.

The wiring structure 500 includes one or more insulating layers 510, one or more wiring layers 520, and one or more vias 530. For example, the wiring structure 500 includes a first wiring layer 521 disposed on the encapsulant 400, a first via 531 that penetrates the encapsulant 400 and electrically connects the first wiring layer 521 and the third wiring layer 223 of the support substrate 200, an insulating layer 510 disposed on the encapsulant 400 and that covers the first wiring layer 521, a second wiring layer 522 disposed on the insulating layer 510, and a second via 532 that penetrates the insulating layer 510 and electrically connects the second wiring layer 522 and the first wiring layer 521.

The description of each of the insulating layer 110, the wiring layer 120, and the via 130 of the wiring structure 100 equally applies to the description of each of the insulating layer 510, the wiring layer 520, and the via 530.

Other components are described as described above in the description of the semiconductor package 1000A.

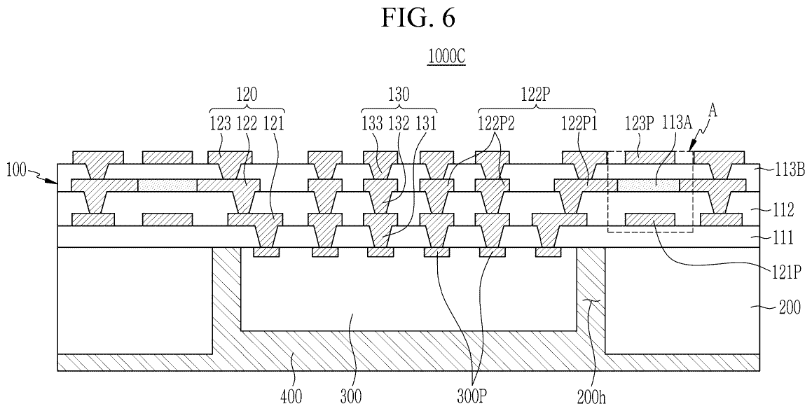

FIG. 6 is a cross-sectional view of a semiconductor package according to an embodiment.

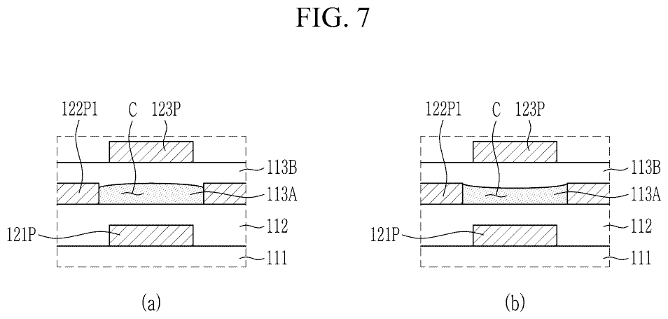

FIG. 7 is an enlarged view of area “A” of FIG. 6.

In a semiconductor package 1000C, in an embodiment, the third insulating layer 113A fills the cavity C of the second wiring pattern 122P1, and the fourth insulating layer 113B covers the second wiring layer 122 and the third insulating layer 113A. Accordingly, in an embodiment, the fourth insulating layer 113B covers side surfaces of the wiring patterns 122P1 and 122P2 in the second wiring layer 122 and is exposed by side surfaces of the wiring structure 100. In addition, the fourth insulating layer 113B fills a space between the second wiring pattern 122P1 and the additional wiring pattern 122P2 and a space between the additional wiring patterns 122P2.

Referring to FIG. 7 (a), in an embodiment, a central portion of one surface of the third insulating layer 113A covered with the fourth insulating layer 113B protrudes from a peripheral portion that surrounds it. In an embodiment, referring to FIG. 7 (b), a central portion of one surface of the third insulating layer 113A covered with the fourth insulating layer 113B is depressed or concave downward from a peripheral portion that surrounds it. As will be described below, the third insulating layer 113A is formed by dispensing an insulating material into the cavity C, and has a structure in which one surface protrudes or is depressed or concave downward, according to a viscosity or a capillary phenomenon of the insulating material.

Other components are described as described above in the description of the other semiconductor package 1000A.

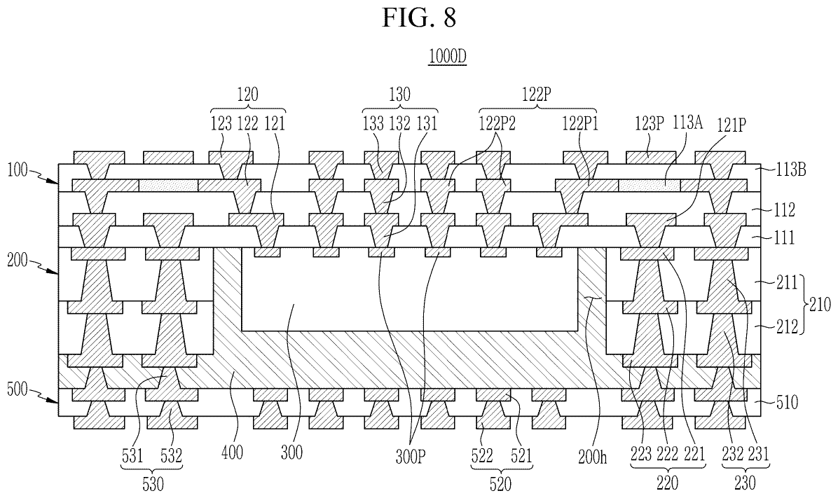

FIG. 8 is a cross-sectional view of a semiconductor package according to an embodiment.

In a semiconductor package 1000D, in an embodiment, the third insulating layer 113A fills the cavity C of the second wiring pattern 122P1, and the fourth insulating layer 113B covers the second wiring layer 122, the third insulating layer 113A and the second insulating layer 112 in a region that overlaps the semiconductor chip 300.

In addition, the support substrate 200 of the semiconductor package 1000D includes one or more insulating layers 210, one or more wiring layers 220, and vias 230. In addition, the semiconductor package 1000D further includes a wiring structure 500 disposed on the support substrate 200 and the encapsulant 400.

Descriptions of other components, including specific components in the support substrate 200 and the wiring structure 500, are as described above in the description of the semiconductor packages 1000A, 1000B, and 1000C.

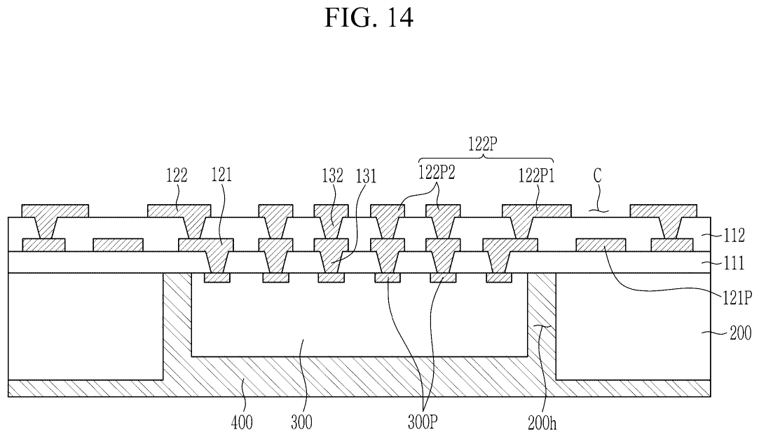

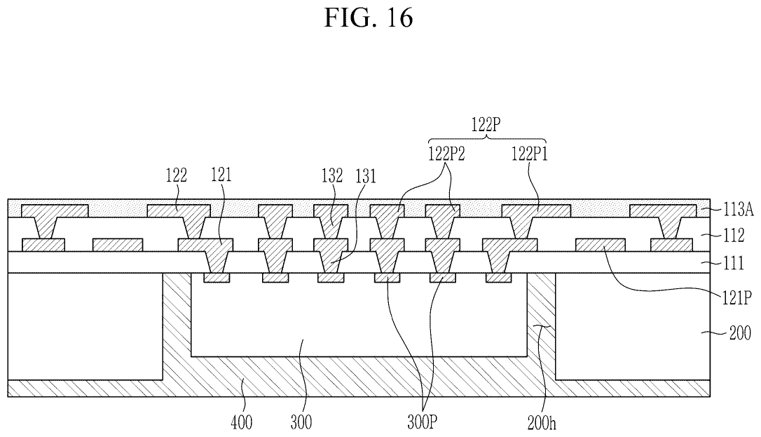

FIG. 14 to FIG. 18 illustrate a process of manufacturing a wiring structure of a semiconductor package according to an embodiment.

Referring to FIG. 14, in an embodiment, the through hole 200h is formed in the support substrate 200, the semiconductor chip 300 is disposed, and the semiconductor chip 300 is encapsulated with the encapsulant 400 to prepare a semiconductor package before the wiring structure 100 is formed. The first insulating layer 111, the first via 131, the first wiring layer 121, the second insulating layer 112, the second via 132, and the second wiring layer 122 that includes the wiring pattern 122P1 with the cavity C are formed on the support substrate 200 and the semiconductor chip 300.

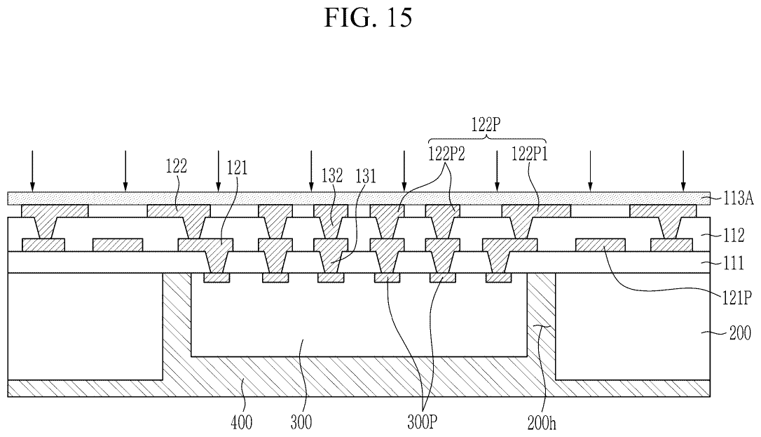

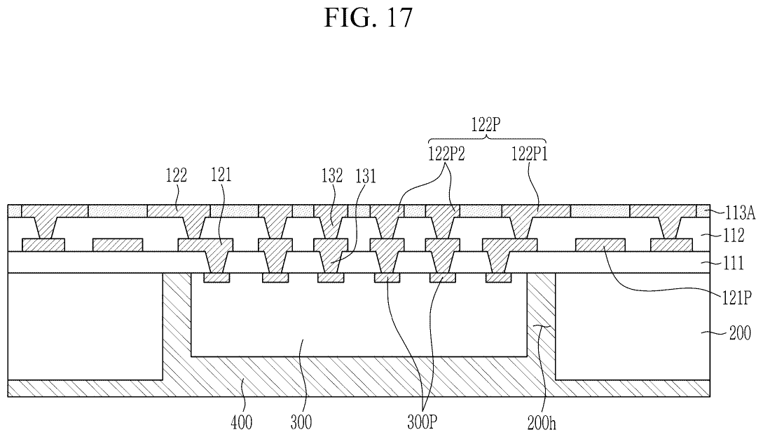

Referring to FIG. 15 and FIG. 17, in an embodiment, the third insulating layer 113A that fills the cavity C is formed. The forming of the third insulating layer 113A includes laminating an insulating material on the second wiring layer 122 and removing the insulating material from the second wiring layer 122. The insulating material to be laminated is a film type. As necessary, the forming of the third insulating layer 113A may further include curing the insulating material after laminating the insulating material. Removing the insulating material from the second wiring layer 122 is performed by, for example, a descum process that uses plasma.

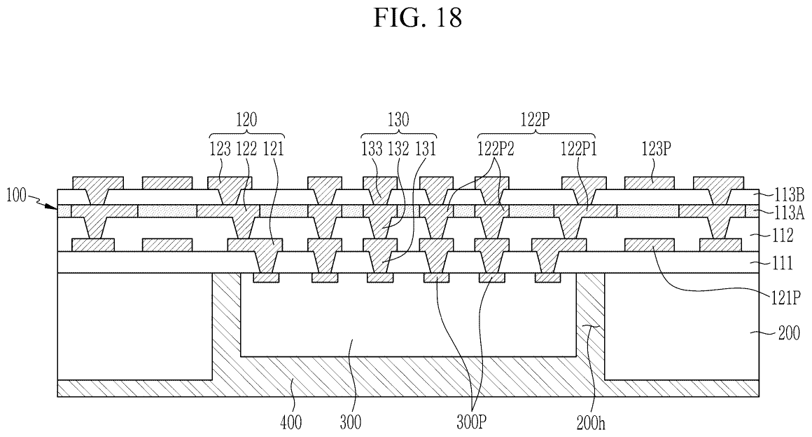

Referring to FIG. 18, in an embodiment, the fourth insulating layer 113B that covers the second wiring layer 122 and the third insulating layer 113A is formed by contacting each of the second wiring layer 122 and the third insulating layer 113A. In addition, the semiconductor package 1000A that includes a wiring structure according to an embodiment is manufactured by forming the third via 133 and the third wiring layer 123 that penetrates the fourth insulating layer 113B.

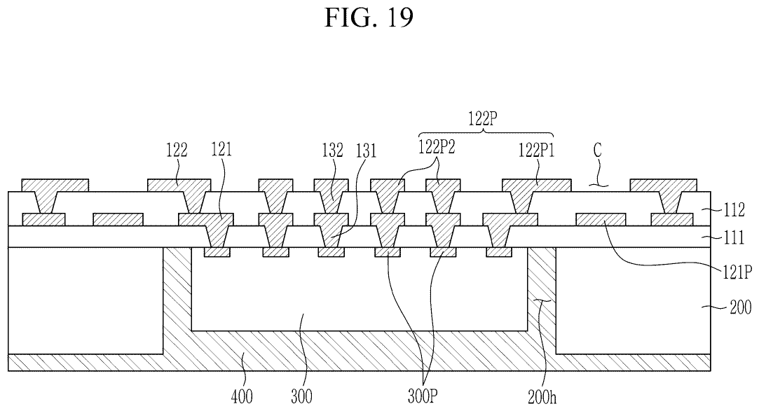

FIG. 19 to FIG. 22 illustrate a process of manufacturing a wiring structure of a semiconductor package according to an embodiment.

Referring to FIG. 19, as in FIG. 14, in an embodiment, a semiconductor package is prepared before the wiring structure 100 is formed, and the first insulating layer 111, the first via 131, the first wiring layer 121, the second insulating layer 112, the second via 132, and the second wiring layer 122 that includes the wiring pattern 122P1 with the cavity C are formed on the support substrate 200 and the semiconductor chip 300.

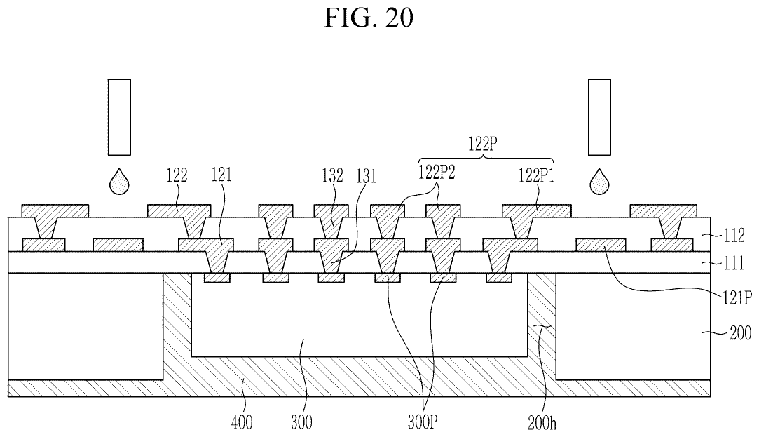

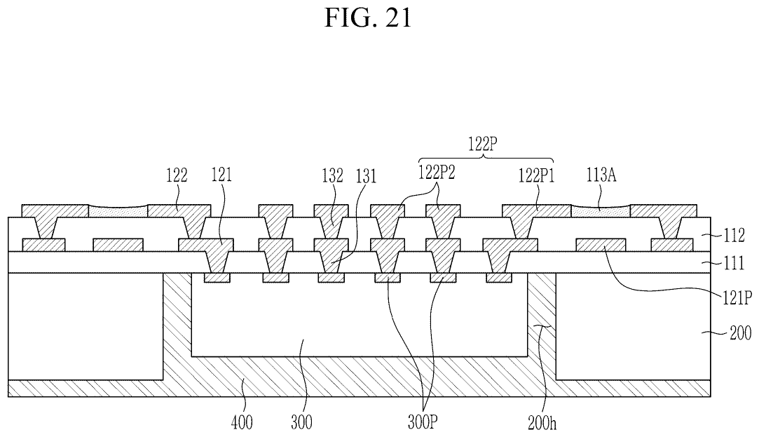

Referring to FIG. 20 and FIG. 21, in an embodiment, the third insulating layer 113A that fills the cavity C is formed. Forming the third insulating layer 113A includes dispensing an insulating material into the cavity C. The insulating material to be dispensed is a liquid insulating material and fills the cavity C through inkjet coating. As necessary, forming the third insulating layer 113A may further include curing the insulating material after dispensing the insulating material.

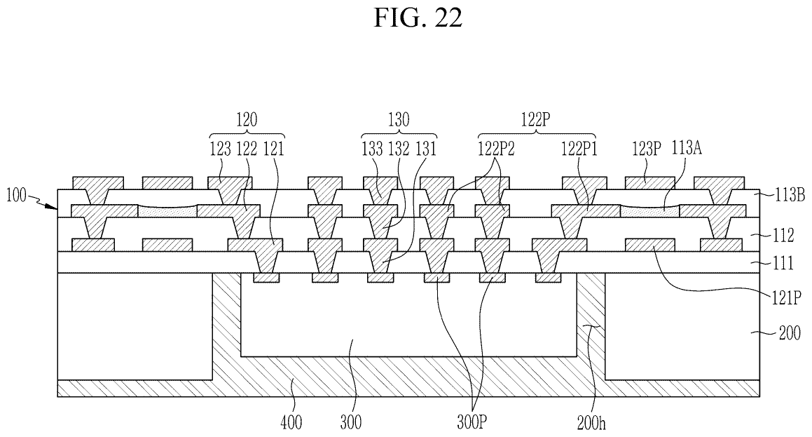

Referring to FIG. 22, in an embodiment, the fourth insulating layer 113B that covers the second wiring layer 122 and the third insulating layer 113A are formed by contacting each of the second wiring layer 122 and the third insulating layer 113A. In addition, the semiconductor package 1000C that includes a wiring structure according to an embodiment is manufactured by forming the third via 133 and the third wiring layer 123 that penetrates the fourth insulating layer 113B.

While embodiments of this disclosure have been described in connection with the figures, it is to be understood that embodiments of the disclosure are not limited to the disclosed embodiments, but, on the contrary, are intended to cover various modifications and equivalent arrangements included within the spirit and scope of the appended claims.

What is claimed is:

1. A wiring structure, comprising:
a plurality of wiring layers; and
a plurality of insulating layers,
wherein the plurality of wiring layers include a first wiring layer that includes a wiring pattern that includes a cavity, and
the plurality of insulating layers include a first insulating layer that fills the cavity, and a second insulating layer that contacts each of the first wiring layer and the first insulating layer and covers the first wiring layer and the first insulating layer.

2. The wiring structure of claim 1, wherein
the first insulating layer covers a side surface of the wiring pattern and is exposed by a side surface of the wiring structure.

3. The wiring structure of claim 2, wherein
a surface of the first insulating layer that is covered with the second insulating layer is located at a same level as a surface of the wiring pattern that is covered with the second insulating layer, or is located lower than the surface of the wiring pattern.

4. The wiring structure of claim 1, wherein
the second insulating layer covers a side surface of the wiring pattern.

5. The wiring structure of claim 4, wherein
a central portion of one surface of the first insulating layer covered with the second insulating layer protrudes above a peripheral portion that surrounds the central portion.

6. The wiring structure of claim 4, wherein
a central portion of one surface of the first insulating layer covered with the second insulating layer is concave downward from a peripheral portion that surrounds the central portion.

7. The wiring structure of claim 1, wherein
the plurality of wiring layers further include a second wiring layer disposed on the second insulating layer and a third wiring layer disposed on the first insulating layer,
the second wiring layer includes a first ground pattern disposed on a first side of the cavity, and
the third wiring layer includes a second ground pattern disposed on a second side of the cavity.

8. The wiring structure of claim 1, wherein
a surface of each of the wiring pattern and the first insulating layer that are opposite to a surface covered with the second insulating layer are coplanar.

9. The wiring structure of claim 1, wherein
a molecular weight of the first insulating layer is 30,000 or more.

10. The wiring structure of claim 1, wherein
a coefficient of thermal expansion (CTE) of the first insulating layer is 100 ppm/° C. or less.

11. The wiring structure of claim 1, wherein
a dielectric constant of the first insulating layer is 4 or less.

12. The wiring structure of claim 1, wherein
the plurality of insulating layers include a thermosetting material, and
a curing temperature of the first insulating layer is the same as or less than a curing temperature of other insulating layers in the plurality of insulating layers.

13. A semiconductor package, comprising:
a wiring structure that includes a plurality of wiring layers and a plurality of insulating layers;
a support substrate disposed on the wiring structure and that includes a through hole;
a semiconductor chip disposed in the through hole and electrically connected to the wiring structure; and
an encapsulant that fills the through hole and encapsulates the semiconductor chip,
wherein the plurality of wiring layers include a first wiring layer that includes a wiring pattern and a cavity, and
the plurality of insulating layers include a first insulating layer that fills the cavity, and a second insulating layer that contacts each of the first wiring layer and the first insulating layer and covers the first wiring layer and the first insulating layer.

14. The semiconductor package of claim 13, wherein
the support substrate includes one or more wiring layers that are electrically connected to the wiring structure.

15. The semiconductor package of claim 13, wherein
the first insulating layer covers a side surface of the wiring pattern and is exposed by a side surface of the wiring structure.

16. The semiconductor package of claim 13, wherein
the second insulating layer covers a side surface of the wiring pattern.

17. A method of manufacturing a wiring structure, comprising:
forming a wiring layer that includes a wiring pattern and a cavity;
forming a first insulating layer that fills the cavity; and
forming a second insulating layer that covers the wiring layer and the first insulating layer by contacting each of the wiring layer and the first insulating layer.

18. The method of manufacturing the wiring structure of claim 17, wherein
forming the first insulating layer includes laminating an insulating material on the wiring layer.

19. The method of manufacturing the wiring structure of claim 18, wherein
forming the first insulating layer further includes removing the insulating material from the wiring layer.

20. The method of manufacturing the wiring structure of claim 17, wherein
forming the first insulating layer includes dispensing an insulating material into the cavity.
